(19) United States
(12) Patent Application Publication
(10) Pub. No.: US 2009/0060691 A1
(43) Pub. Date: Mar. 5, 2009

(54) SUBSTRATE RECEIVING APPARATUS AND SUBSTRATE RECEIVING METHOD

(75) Inventor: Shinji WAKABAYASHI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/199,270

(22) Filed: Aug. 27, 2008

Related U.S. Application Data
(60) Provisional application No. 60/982,754, filed on Oct. 26, 2007.

(30) Foreign Application Priority Data
Aug. 28, 2007 (JP) 2007-221310

(51) Int. Cl. H01L 21/67

(52) U.S. Cl. 414/222.02; 414/806; 414/217

(57) ABSTRACT

A substrate receiving apparatus is capable of reducing the size of a substrate processing system. The substrate receiving apparatus is connected to a vacuum processing apparatus. The vacuum processing apparatus performs processing on a substrate. A connecting portion of the substrate receiving apparatus is connected to a container. The container houses a holding member holding a plurality of the substrates. A communication control portion controls a communication between an internal space in the substrate receiving apparatus and the interior of the container, and isolates the internal space from the interior. A holding member transferring-in portion takes the holding member out of the container and transfers the holding member into the internal space. A pressure control portion changes the internal space between an atmospheric pressure and a vacuum by controlling the pressure in the internal space isolated from the interior of the container.

### BACKGROUND OF THE INVENTION

1. Field of the Invention

The present invention relates to a substrate receiving apparatus and, more particularly, to a substrate receiving apparatus having a connecting portion to which a container housing a plurality of substrates is connected and capable of changing between the atmospheric pressure and a vacuum, and to a substrate receiving method using the apparatus.

2. Description of the Related Art

Conventionally, as a processing system in which plasma processing is performed on a surface of a semiconductor wafer (hereinafter referred to as “wafer”) provided as a substrate, a substrate processing system such as shown in FIG. 10 is known.

Referring to FIG. 10, a substrate processing system 50 is provided with a processing module 55 arranged to perform plasma processing on each of wafers W, a loader module 51 having connecting ports (not shown) to which front opening unified pods (FOUPs) 52 described below are connected, and arranged to take out each wafer W in the FOUP 52 via the connecting port, a load lock module 53 having a receiving platform 58 which receives wafer W, and a transfer module 54 arranged to transfer each wafer W from the interior of the load lock module 53 to the interior of the processing module 55. The loader module 51 has the shape of a rectangular parallelepipedal box and has FOUP mounting platforms 56 on a side surface in which the connecting ports are provided.

Each of the processing module 55 and the transfer module 54 is maintained in its interior under vacuum. The loader module 51 is maintained in its interior under atmospheric pressure at all times, while the load lock module 53 is constructed so as to be capable of changing the interior between the atmospheric pressure and the vacuum. The loader module 51 and the load lock module 53 are connected to each other through a gate valve 59; the load lock module 53 and the transfer module 54 through a gate valve 60; and the transfer module 54 and the processing module 55 through a gate valve 62.

A scalar-type transfer arm 57 for transferring each wafer W is disposed in the loader module 51. The wafer W in the FOUP 52 is transferred onto and mounted on an upper surface of the receiving platform 58 in the load lock module 53 by the transfer arm 57. A scalar-type transfer arm 61 for transferring each wafer W is also disposed in the transfer module 54. The wafer W on the receiving platform 58 is transferred into the processing module 55 by the transfer arm 61.

A susceptor 64 as a lower electrode on which a wafer W is mounted and an upper electrode 63 are disposed in the processing module 55. On the wafer W transferred and mounted onto an upper surface of the susceptor 64 by the transfer arm 61, plasma processing is performed by plasma produced in a processing space in the processing module 55.

FIG. 11 is a perspective view schematically showing the construction of the FOUP in which wafers W are housed.

Referring to FIG. 11, the FOUP 52 is a transfer container standardized in accordance with the Semiconductor Equipment and Materials International (SEMI). The FOUP 52 has a main body 71 which is a container having an upper surface U-shaped as viewed from above, and having a shape formed by being extruded from the upper surface, and which has an opening at its side opposite from its curved side surface, and a lid 72 opposed to the side opening of the main body 71 and that enables this opening to be opened and closed freely. The main body 71 has a plurality of slots (not shown) in the form of channels capable of housing wafers W parallel to the upper surface while holding peripheral edge portions of the wafers W. A plurality of wafers W are respectively inserted in the slots to be housed in parallel with each other. The lid 72 has sealing rubber made of NBR or the like on its peripheral edge portion into contact with the main body 71, whereby the inside of the main body 71 can be tightly sealed. Each of the main body 71 and the lid 72 is made of a resin such as ABS (See, for example, Japanese Laid-Open Patent Publication (Kokai) No. 2005-150259).

In the above-described substrate processing system 50, however, there is a need to bring the lid 72 opposed to the side opening of the FOUP 52 into contact with the connecting port provided in the side surface of the loader module 51. There is, therefore, a need to dispose the FOUP mounting platforms 56 on which the FOUP 52 are mounted and the loader module 51 side by side. Also, in the substrate processing system 50, the interior of the transfer module 54 is maintained under vacuum while the interior of the loader module 51 is maintained at atmospheric pressure. There is, therefore, a need to dispose between the transfer module 54 and the loader module 51 the load lock module 53 capable of changing the interior between the atmospheric pressure and the vacuum.

That is, in the substrate processing system 50, because of the need to dispose the FOUP mounting platform 56, the loader module 51 and the load lock module 53 side by side, there is a problem that a large occupied area (foot print) is required, for example, on the premises of a factory for disposing the substrate processing system 50. Also, there has been a tendency toward a large wafer size in recent years, and it is conceivable that the sizes of modules including the loader module 51 will be increased in correspondence with the increase in wafer size.

### SUMMARY OF THE INVENTION

The present invention provides a substrate receiving apparatus and a substrate receiving method capable of reducing the size of a substrate processing system.

Accordingly, in a first aspect of the present invention, there is provided a substrate receiving apparatus generally in the form of a box connected to a vacuum processing apparatus in which processing is performed on a substrate, the substrate receiving apparatus comprising a connecting portion which is provided in a ceiling portion of the substrate receiving apparatus, and to which a container housing a holding member holding a plurality of the substrates is connected, a communication control portion adapted to control a communication between an internal space in the substrate receiving apparatus and the interior of the container connected to the connecting portion, and to isolate the internal space from the interior of the container, a holding member transferring-in portion adapted to take the holding member out of the interior of the container and transfer the holding member into the internal space via the connecting portion, and a pressure control portion adapted to change the internal space between an atmospheric pressure and a vacuum by controlling the pressure in the internal space isolated from the interior of the container.

According to the first aspect of the present invention, the connecting portion provided in the ceiling portion of the substrate receiving apparatus is connected to the container housing the holding member holding a plurality of substrates, and the holding member is transferred into the internal space of the substrate receiving apparatus via the connecting portion. Therefore, the need for disposing mounting platforms on which the containers to be connected to the connecting portion are mounted by the side of the substrate receiving apparatus can be eliminated. The internal space isolated from the interior of the container in the substrate receiving apparatus is changed between the atmospheric pressure and the vacuum. Therefore, the substrate receiving apparatus and the vacuum processing apparatus can be connected to each other without interposing an atmosphere-vacuum changeable transfer chamber therebetween. Consequently, the size of the substrate processing system can be reduced.

The first aspect of the present invention can provide a substrate receiving apparatus, wherein the pressure control portion includes an introducing portion adapted to introduce a gas into the internal space and an exhaust portion adapted to exhaust the gas from the internal space.

According to the first aspect of the present invention, the pressure in the internal space is controlled by introducing a gas into the internal space and by exhausting the gas from the internal space. Therefore, the pressure in the internal space can be controlled easily and speedily.

The first aspect of the present invention can provide a substrate receiving apparatus, wherein the communication control portion is a closable and openable door valve.

According to the first aspect of the present invention, change between the communication and the isolation between the internal space of the substrate receiving apparatus and the interior of the container can be controlled easily and reliably by opening and closing the door valve.

The first aspect of the present invention can provide a substrate receiving apparatus, wherein the holding member transferring-in portion is disposed in the internal space and includes a mounting member on which the holding member is mounted, and a supporting member supporting the mounting member, and the mounting member can be moved upward and downward in a ceiling-bottom direction.

According to the first aspect of the present invention, the mounting member on which the holding member is mounted can be moved upward and downward in the ceiling-bottom direction in the internal space such as to easily transfer the holding member housed in the container connected to the connecting portion in the ceiling portion into the internal space of the substrate receiving apparatus.

The first aspect of the present invention can provide a substrate receiving apparatus, wherein a gas is introduced into the internal space in a state where the internal space is isolated from the interior of the container.

According to the first aspect of the present invention, the pressure is controlled by introducing the gas into the internal space in a state where the internal space is isolated from the interior of the container. Therefore, a pressure difference between the interior of the container and the internal space can be eliminated and the occurrence of air flows in the internal space and the interior of the container due to such a pressure difference can be prevented when the communication is established between the internal space and the interior of the container. Thus, the generation of particles caused by air flows can be reduced. Therefore it is possible to prevent contamination of the substrate surface by particles.

The first aspect of the present invention can provide a substrate receiving apparatus, wherein the gas introduced into the internal space is an inert gas.

According to the first aspect of the present invention, the gas introduced into the internal space is an inert gas. Therefore, the occurrence of chemical reactions including oxidation on the substrates transferred into the internal space can be suppressed. Also, the occurrence of corrosion in the substrate receiving apparatus can be suppressed.

The first aspect of the present invention can provide a substrate receiving apparatus further comprising an in-container gas introducing portion adapted to introduce an inert gas into the container.

According to the first aspect of the present invention, an inert gas is introduced into the interior of the container to suppress the occurrence of chemical reactions including oxidation on the substrates transferred into the container.

The first aspect of the present invention can provide a substrate receiving apparatus, wherein the container has a main body generally in the form of a box having an opening at its bottom, and a lid capable of opening and closing the opening, and the lid is removed to open the opening after the completion of the connection between the container and the connecting portion.

According to the first aspect of the present invention, the lid is removed to open the opening after the completion of the connection between the container and the connecting portion. Therefore, the communication can be easily established between the interior of the container and the internal space by mounting the container on the ceiling portion of the substrate receiving apparatus.

Accordingly, in a second aspect of the present invention, there is provided a substrate receiving method for a substrate receiving apparatus generally in the form of a box connected to a vacuum processing apparatus in which processing is performed on a substrate, the method comprising a connecting step of connecting a container housing a holding member holding a plurality of the substrates to a connecting portion disposed in a ceiling portion of the substrate receiving apparatus, a first communication step of establishing a communication between an internal space in the substrate receiving apparatus and the interior of the container, a transferring-in step of taking the holding member out of the interior of the container and transferring the holding member into the internal space via the connecting portion, an isolation step of isolating the internal space and the interior of the container from each other, an evacuation step of evacuating the isolated internal space, a transfer step of transferring the plurality of the substrates held in the transferred-in holding member into the vacuum processing apparatus on a substrate-by-substrate basis, and transferring the vacuum-processed substrates from the vacuum processing apparatus to the internal space on a substrate-by-substrate basis to let the substrates held on the holding member, a gas introducing step of introducing a gas into the internal space after performance of the vacuum processing on the substrates, a second communication step of establishing a communication between the internal space having the gas introduced therein and the interior of the container, and a transferring-out step of transferring the holding member holding the plurality of vacuum-processed substrates from the internal space of the receiving apparatus into the container.

According to the second aspect of the present invention, the substrates are transferred from the evacuated internal space of the substrate receiving apparatus into the vacuum processing apparatus on a substrate-by-substrate basis. Therefore, there is not need for change between the atmospheric pressure and the vacuum during transfer of the plurality of substrates. As a result, the throughput of substrate processing in the vacuum processing system can be improved.

The features and advantages of the invention will become more apparent from the following detailed description taken in conjunction with the accompanying drawings.

### BRIEF DESCRIPTION OF THE DRAWINGS

FIG. 1 is a schematic sectional view of the construction of a substrate processing system having a substrate receiving apparatus according to an embodiment of the present invention.

FIG. 2 is process drawings showing lot processing on wafers in the substrate processing system shown in FIG. 1.

FIG. 3 is process drawings showing lot processing on wafers in the substrate processing system shown in FIG. 1.

FIG. 4 is process drawings showing lot processing on wafers in the substrate processing system shown in FIG. 1.

FIG. 5 is process drawings showing lot processing on wafers in the substrate processing system shown in FIG. 1.

FIG. 6 is process drawings showing lot processing on wafers in the substrate processing system shown in FIG. 1.

FIG. 7 is process drawings showing lot processing on wafers in the substrate processing system shown in FIG. 1.

FIG. 8 is a flowchart of lot processing on wafers in the substrate processing system shown in FIG. 1.

FIG. 9 is a schematic sectional view of the construction of a variation of the substrate receiving apparatus according to the present embodiment.

FIG. 10 is a schematic sectional view of the construction of a conventional substrate processing system.

FIG. 11 is a perspective view schematically showing the construction of a FOUP in which wafers W are housed.

### DETAILED DESCRIPTION OF THE PREFERRED EMBODIMENTS

An embodiment of the present invention will be described with reference to the accompanying drawings.

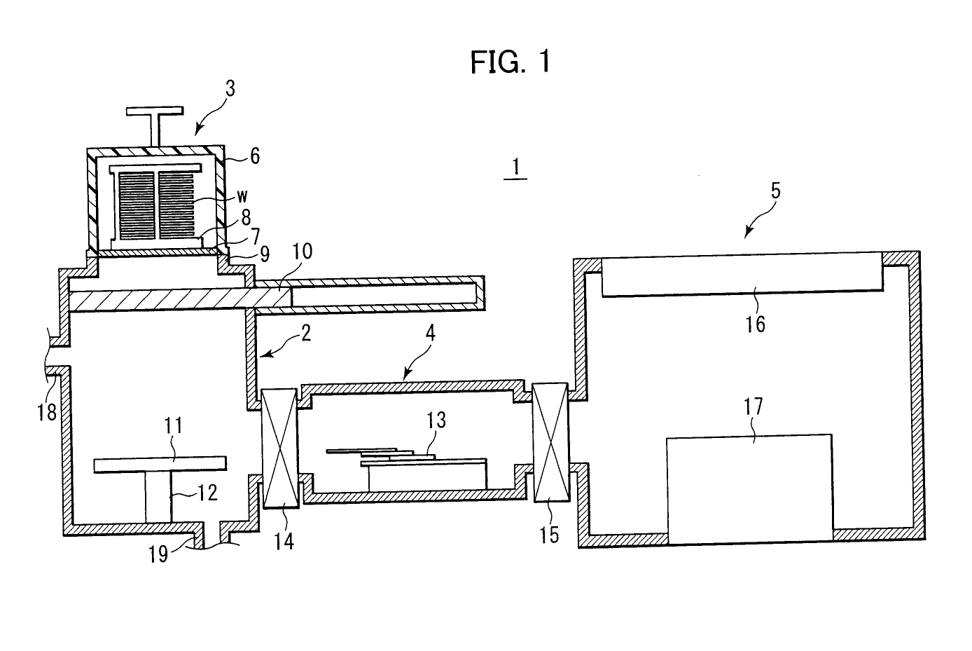

FIG. 1 is a schematic sectional view of the construction of a substrate processing system having a substrate receiving apparatus according to the present embodiment.

Referring to FIG. 1, a substrate processing system 1 is provided with a processing module 5 (vacuum processing apparatus) arranged to perform any one of various kinds of plasma processing such as film forming, diffusion and etching on wafers W, a cassette module 2 (substrate receiving apparatus), and a transfer module 4 disposed between the cassette module 2 and the processing module 5 to transfer wafers from the cassette module 2 into the processing module 5 and from the processing module 5 into the cassette module 2.

Each of the transfer module 4 and the processing module 5 is maintained in its interior under vacuum at the time of substrate processing, and the cassette module 2 is constructed so as to be capable of changing its interior between the atmospheric pressure and the vacuum, as described below. The cassette module 2 and the transfer module 4 are connected to each other through a gate valve 14, and the transfer module 4 and the processing module 5 are connected to each other through a gate valve 15.

The cassette module 2 generally in the form of a box has a port 9 (connecting portion) provided in a ceiling portion, a door valve 10 (communication control portion) which is a sliding-type valve, an exhaust port 19 (pressure control portion, exhaust portion) and a gas introduction port 18 (pressure control portion, introducing portion). A container 3 described below is connected to the port 9. The door valve 10 is disposed immediately below the port 9 in an internal space of the cassette module 2 and is constructed so that a valve member can be caused to project into the internal space as desired. The pressure in the internal space is reduced to a vacuum by evacuation through the exhaust port 19 and is increased to the atmospheric pressure by introducing a gas through the gas introduction port 18. Further, a mounting member 11 (holding member transferring-in portion) on which a cassette 8 (holding member) described below is mounted and a supporting member 12 (holding member transferring-in portion) on which the mounting member 11 is supported are disposed in the cassette module 2. One end of the supporting member 12 supports the mounting member 11, and the other end of the supporting member 12 is connected to an inner bottom surface of the cassette module 2. The supporting member 12 has a lift mechanism (not shown) to enable the mounting member 11 to be vertically moved as desired in a direction between the ceiling portion and bottom of the cassette module 2.

The container 3 is a so-called bottom opening pod (hereinafter referred to simply as “BOP”) having a main body 6 constructed so as to be capable of housing the cassette 8, having a generally box-like shape with an opening at the bottom, and a lid 7 that enables the opening to be opened and closed freely. When the opening is closed by the lid 7, the interior of the container 3 is isolated from the surrounding atmosphere. In a state where the container 3 is connected to the port 9, the opening is opened by removal of the lid 7 from the main body 6 to be connected to the port 9, thereby establishing a communication between the port 9 and the interior of the container 3 and, hence, a communication between the internal space of the cassette module 2 and the interior of the container 3 is established. In this state, the valve member of the door valve 10 is caused to project into the internal space (valve closing) to isolate the internal space from the interior of the container 3, or is retracted from the internal space (valve opening) to establish the communication between the internal space and the interior of the container 3.

The cassette 8 is a frame having a plurality of slots in the form of channels (not shown) capable of housing wafers W parallel to an upper surface of the frame while holding peripheral edge portions of the wafers, as is the FOUP 52. A plurality of wafers W are respectively inserted in the slots to be held in parallel with each other.

The transfer module 4 has a retractable and turnable scalar-type transfer arm 13 disposed therein. With the transfer arm 13, wafers W held in the cassette 8 mounted on an upper surface of the mounting member 11 are transferred onto and mounted on an upper surface of a susceptor 17 in the processing module 5 described below, on a wafer-by-wafer basis.

The processing module 5 has the susceptor 17 disposed on an inner bottom surface of the processing module 5 as a lower electrode on which a semiconductor wafer W is mounted, and an upper electrode 16 disposed by being opposed to the susceptor 17 and formed into the shape of a flat hollow disk. The susceptor 17 attracts and holds the wafer W by Coulomb force from an electrostatic chuck (not shown) or the like attached to an upper surface thereof. A focus ring (not shown) is disposed on the periphery of the surface of the susceptor 17 on which the wafer W is attracted and held. The focus ring converges plasma produced in a processing space between the susceptor 17 and the upper electrode 16 toward the wafer W. By the converged plasma, the surface of the wafer W on the susceptor 17 is plasma-processed.

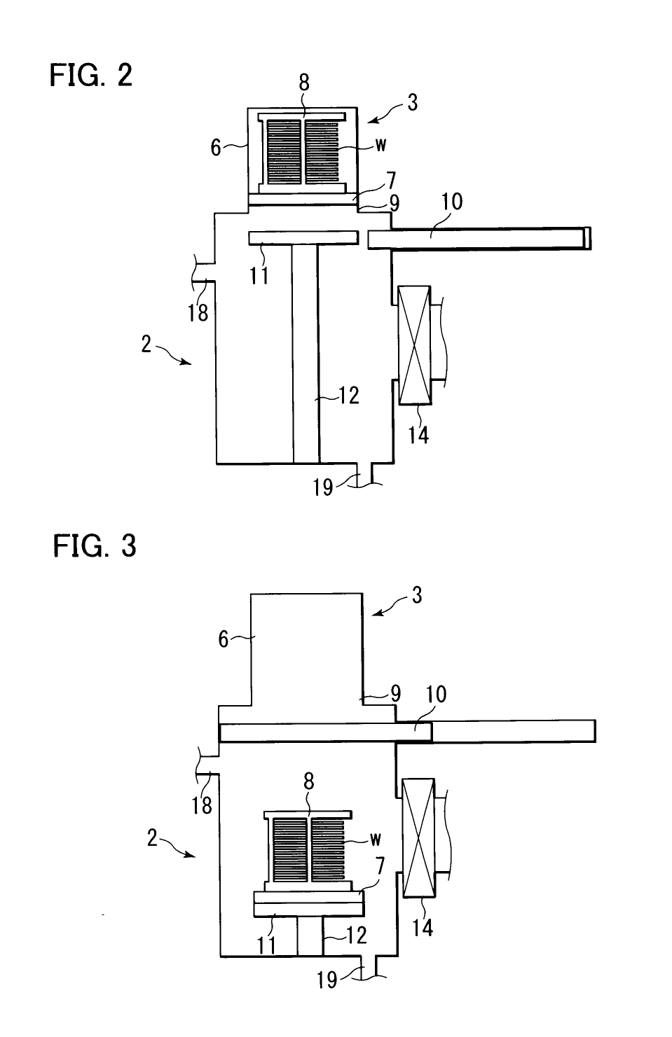

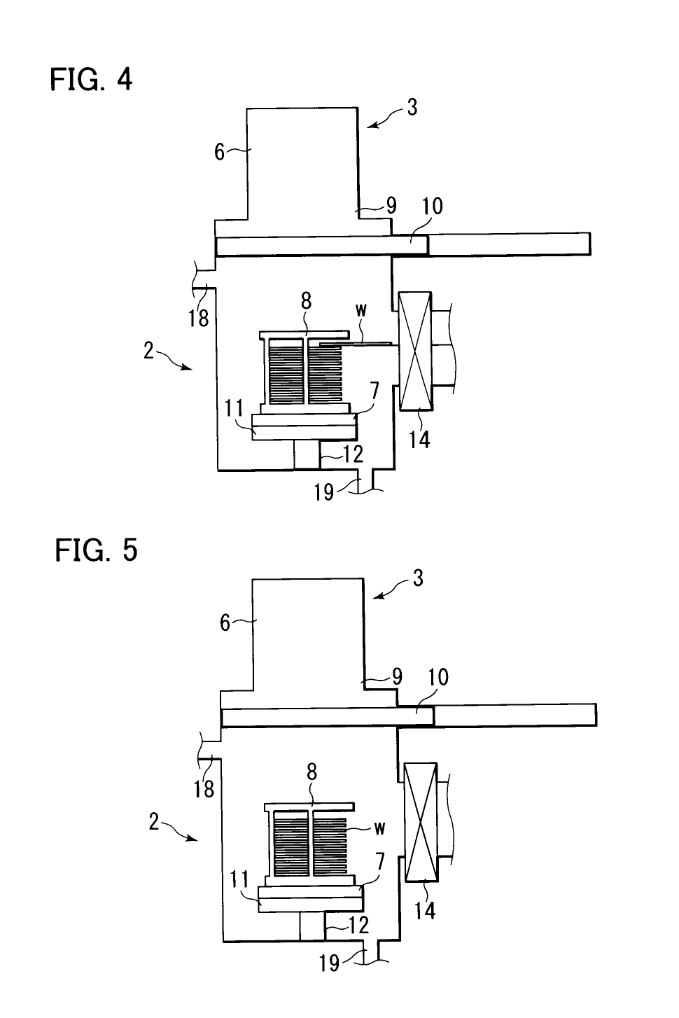

Lot processing on wafers W in the present embodiment will be described with reference to FIGS. 2 to 8. This processing is executed by a CPU not illustrated, which controls the substrate processing system.

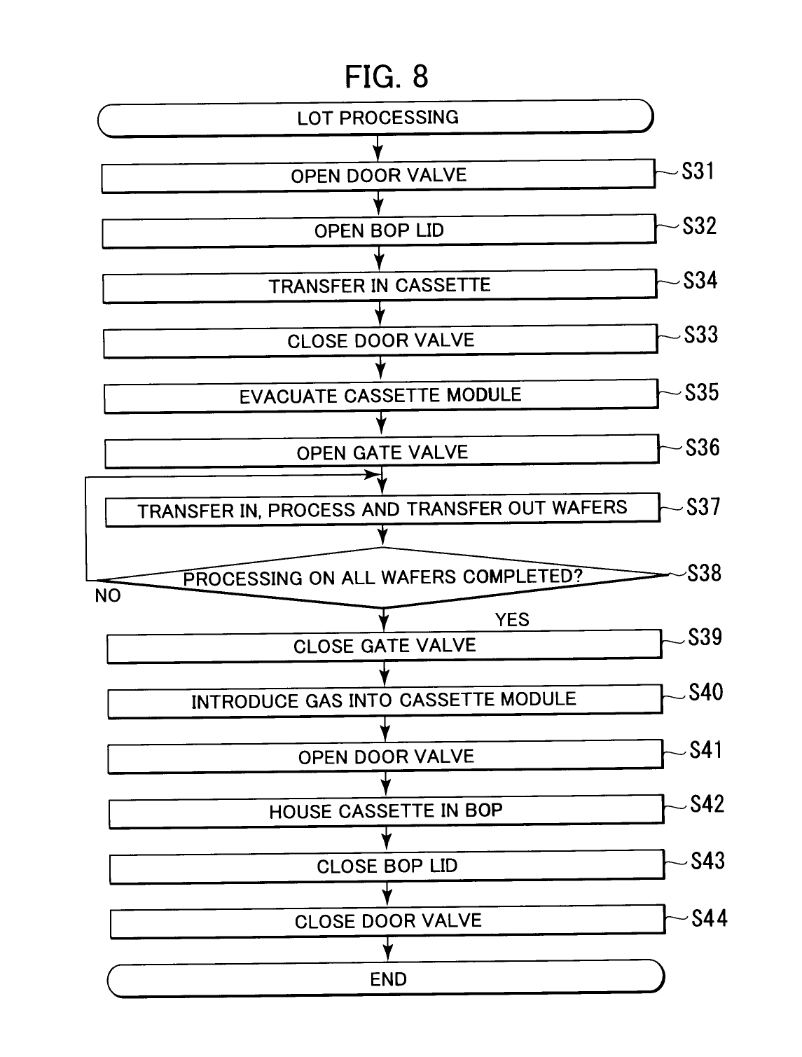

FIGS. 2 to 7 are process drawings showing lot processing on wafers in the substrate processing system shown in FIG. 1. FIG. 8 is a flowchart of lot processing on wafers in the substrate processing system shown in FIG. 1.

First, as shown in FIG. 2, the container 3 housing the cassette 8 holding one lot (e.g., 25 sheets) of wafers W is mounted in the ceiling portion to be connected to the port 9, and the door valve 10 is opened (step S31). Thereafter, the lid 7 of the container 3 is opened (step S32). The mounting member 11 disposed in the internal space of the cassette module 2 is then moved upward in the direction toward the ceiling portion of the cassette module 2 to receive the lid 7 and the cassette 8. The mounting member 11 that has received the lid 7 and the cassette 8 is moved downward in the direction toward the bottom of the cassette module 2 to transfer the cassette 8 into the internal space (step S33). Thereafter, the door valve 10 is closed to isolate the internal space from the interior of the container 3 (step S34) as shown in FIG. 3. The internal space is evacuated to change the pressure in the internal space from the atmospheric pressure to a vacuum (step S35).

Next, the gate valve 14 is opened (step S36) and the transfer arm 13 disposed in the transfer module 4 is extended into the internal space to take out wafers W held in the cassette 8 one after another. The transfer arm 13 transfers each taken-out wafer W into the processing module 5 through the transfer module 4 and mounts the wafer on the susceptor 17. Also, the transfer arm 13 transfers wafers W on which plasma processing has been performed in the processing module 5 into the cassette module 2 to let the wafers again held in the cassette 8 (step S37). A determination is made as to whether or not plasma processing has been performed on all the wafers W in the one lot (step S38). If plasma processing has not been performed on all the wafers W (NO in step S38), the process returns to step S37. If plasma processing has been performed on all the wafers W (YES in step S38), the gate valve 14 is closed (step S39).

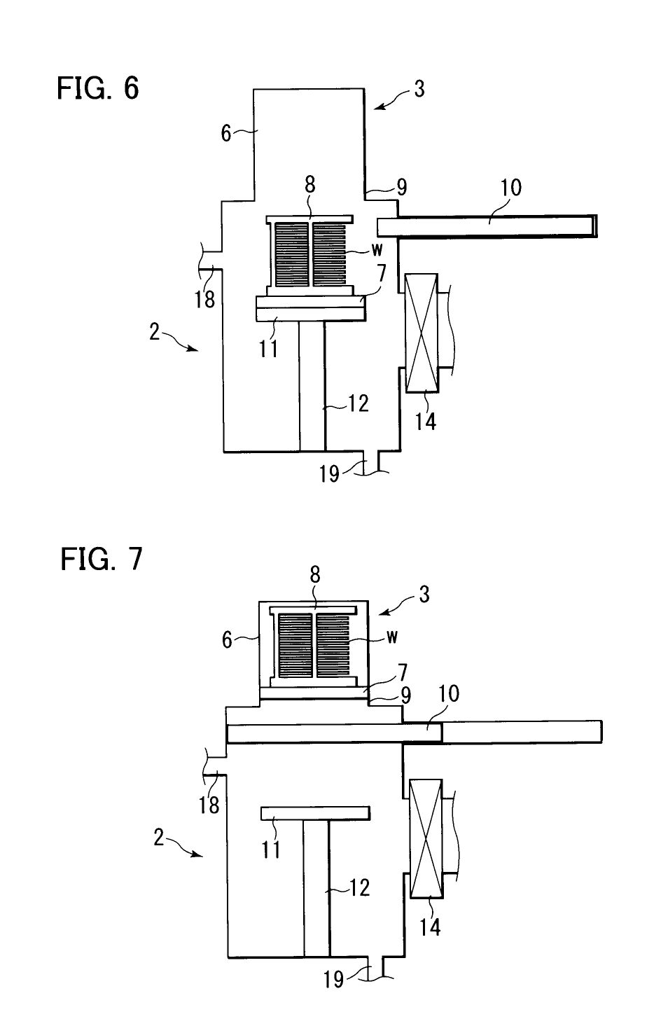

Next, a gas is introduced into the internal space to change the pressure in the internal space from the vacuum to the atmospheric pressure (step S40) and the door valve 10 is thereafter opened to establish a communication between the internal space and the interior of the container 3 (step S41). The mounting member 11 is moved upward to house in the container 3 the cassette 8 holding the plasma-processed wafers W (step S42), as shown in FIG. 6. Subsequently, the lid 7 is closed (step S43) and the door valve 10 is closed, thereby isolating the internal space from the interior of the container 3 (step S44), as shown in FIG. 7. The process then ends.

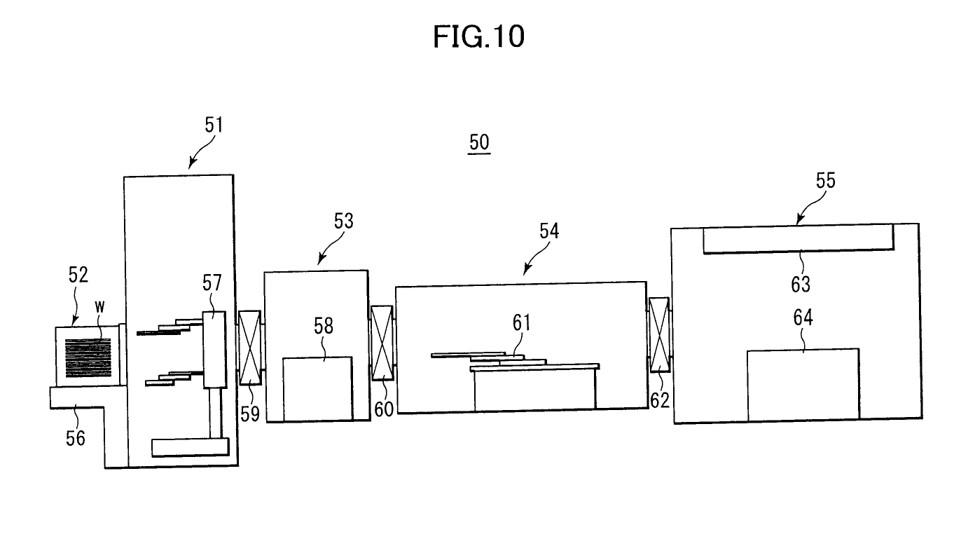

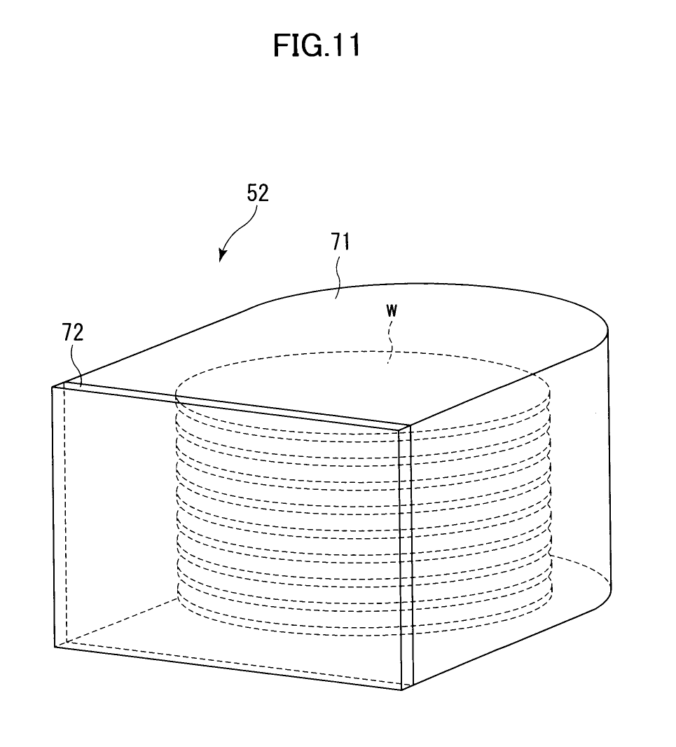

In the cassette module 2 provided as the substrate receiving apparatus according to the present embodiment, the port 9 disposed in the ceiling portion is provided, so that the container 3, which is a so-called BOP, can be connected to the port 9 by mounting the container 3 on the ceiling portion. Thus, there is no need to connect the container 3 to a side of the cassette module 2, and the need for disposing a platform, e.g., the FOUP mounting platform 56 shown in FIG. 10 by the side of the cassette module 2 can be eliminated. Also, since the internal space of the cassette module 2 isolated from the interior of the container 3 can be changed between the atmospheric pressure and the vacuum, the cassette module 2 and the processing module 5 can be indirectly connected to each other without interposing a unit capable of changing the interior between the atmospheric pressure and the vacuum, e.g., the load lock module 53 shown in FIG. 10. Consequently, the size of the substrate processing system 1 can be reduced.

A transfer mechanism such as the transfer arm 13 may be provided in the cassette module 2 or the processing module 5 to enable the cassette module 2 and the processing module 5 to be connected directly to each other.

The pressure in the internal space is controlled by introducing a gas into the internal space through the gas introduction port 18 and by exhausting the internal space of the gas through the exhaust port 19. Therefore, the pressure in the internal space can be controlled easily and speedily. The same effect may also be obtained by providing a relief valve for controlling communication with the atmosphere instead of the gas introduction port 18.

Also, it is possible to control changing between the communication and the isolation between the internal space of the cassette module 2 and the interior of the container 3 with facility and reliability by opening/closing the slide-type door valve 10.

The mounting member 11 can be moved upward/downward in the ceiling-bottom direction in the internal space. Therefore, the cassette 8 housed in the container 3 connected to the port 9 can be easily transferred into the internal space by moving the mounting member 11.

The pressure in the internal space is controlled by introducing a gas therein in a state where the internal space is isolated from the interior of the container 3. Therefore, a pressure difference between the interior of the container 3 and the internal space can be eliminated and the occurrence of air flows in the internal space and the interior of the container 3 due to such a pressure difference can be prevented when the communication is established between the internal space and the interior of the container 3. Thus, the generation of particles caused by air flows can be reduced. Therefore it is possible to prevent contamination of the substrate surface by particles.

The gas introduced into the internal space is preferably an inert gas. For example, if the gas is N₂ gas, the occurrence of chemical reactions including oxidation on wafers W transferred into the internal space can be reduced. Also, the occurrence of corrosion in the cassette module 2 can be reduced.

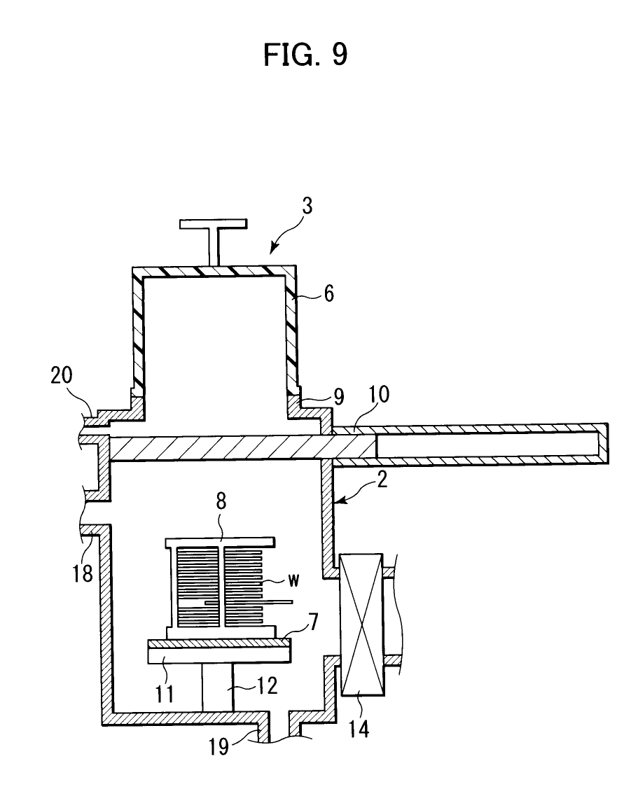

A gas introduction port 20 (in-container gas introducing portion) may be provided in a portion of the cassette module 2 communicating with the interior of the container 3 in a state where the interior of the container 3 is isolated from the internal space, as shown in FIG. 9. With this arrangement, an inert gas is introduced into the container 3 to reduce the occurrence of chemical reactions including oxidation on wafers W transferred into the container 3.

In the processing shown in FIG. 8, wafers W are transferred from the evacuated internal space into the processing module 5. Therefore, there is not need for changing the internal space between the atmospheric pressure and the vacuum on a wafer-by-wafer basis during transfer of a plurality of wafers W, for example, as in the load lock module 53 shown in FIG. 10. As a result, the throughput of processing on wafers W in the vacuum processing system 1 can be improved. In lot processing on wafers W according to the present embodiment, the gate valve 14 is closed when plasma processing is performed in all the wafers W in one lot. However, the gate valve may be closed after performing plasma processing on a certain number of wafers W set as desired.

While the substrate is a semiconductor wafer in the above-described embodiment, the substrate is not limited to the semiconductor wafer. The substrate may alternatively be any of glass substrates such as those for liquid crystal displays (LCDs) or flat panel displays (FPDs).

What is claimed is:

1. A substrate receiving apparatus generally in the form of a box connected to a vacuum processing apparatus in which processing is performed on a substrate, the substrate receiving apparatus comprising:
a connecting portion which is provided in a ceiling portion of the substrate receiving apparatus, and to which a container housing a holding member holding a plurality of the substrates is connected;
a communication control portion adapted to control a communication between an internal space in the substrate receiving apparatus and the interior of the container connected to said connecting portion, and to isolate the internal space from the interior of the container;
a holding member transferring-in portion adapted to take the holding member out of the interior of the container and transfer the holding member into the internal space via said connecting portion; and
a pressure control portion adapted to change the internal space between an atmospheric pressure and a vacuum by controlling the pressure in the internal space isolated from the interior of the container.

2. The substrate receiving apparatus according to claim 1, wherein said pressure control portion includes an introducing portion adapted to introduce a gas into the internal space and an exhaust portion adapted to exhaust the gas from the internal space.

3. The substrate receiving apparatus according to claim 1, wherein said communication control portion is a closable and openable door valve.

4. The substrate receiving apparatus according to claim 1, wherein the holding member transferring-in portion is disposed in the internal space and includes a mounting member on which the holding member is mounted, and a supporting member supporting the mounting member, and the mounting member can be moved upward and downward in a ceiling-bottom direction.

5. The substrate receiving apparatus according to claim 1, wherein a gas is introduced into the internal space in a state where the internal space is isolated from the interior of the container.

6. The substrate receiving apparatus according to claim 5, wherein the gas introduced into the internal space is an inert gas.

7. The substrate receiving apparatus according to claim 1, further comprising an in-container gas introducing portion adapted to introduce an inert gas into the container.

8. The substrate receiving apparatus according to claim 1, wherein the container has a main body generally in the form of a box having an opening at its bottom, and a lid capable of opening and closing the opening, and the lid is removed to open the opening after the completion of the connection between the container and said connecting portion.

9. A substrate receiving method for a substrate receiving apparatus generally in the form of a box connected to a vacuum processing apparatus in which processing is performed on a substrate, the method comprising:
a connecting step of connecting a container housing a holding member holding a plurality of the substrates to a connecting portion disposed in a ceiling portion of the substrate receiving apparatus;
a first communication step of establishing a communication between an internal space in the substrate receiving apparatus and the interior of the container;
a transferring-in step of taking the holding member out of the interior of the container and transferring the holding member into the internal space via the connecting portion;
an isolation step of isolating the internal space and the interior of the container from each other;
an evacuation step of evacuating the isolated internal space;
a transfer step of transferring the plurality of the substrates held in the transferred-in holding member into the vacuum processing apparatus on a substrate-by-substrate basis, and transferring the vacuum-processed substrates from the vacuum processing apparatus to the internal space on a substrate-by-substrate basis to let the substrates held on the holding member;
a gas introducing step of introducing a gas into the internal space after performance of the vacuum processing on the substrates;
a second communication step of establishing a communication between the internal space having the gas introduced therein and the interior of the container; and
a transferring-out step of transferring the holding member holding the plurality of vacuum-processed substrates from the internal space of the receiving apparatus into the container.
